(19) United States
(12) Patent Application Publication
(10) Pub. No.: US 2026/0298997 A1
(43) Pub. Date: Oct. 1, 2026

(54) DEVICE FOR LOCATING ELECTRICAL FAULTS IN UNDERGROUND CABLES

(71) Applicant: Paul Anthony Thomas, Austin, TX (US)

(72) Inventor: Paul Anthony Thomas, Austin, TX (US)

(21) Appl. No.: 19/389,810

(22) Filed: Nov. 14, 2025

Related U.S. Application Data
(60) Provisional application No. 63/780,758, filed on Mar. 31, 2025.

(51) Int. Cl. G01R 31/08; G01R 31/58

(52) U.S. Cl. CPC G01R 31/083; G01R 31/58

(57) ABSTRACT

A device for locating cable fault damage in a cable located underground comprises an RF signal generator which creates an RF signal, a transmitter transmitting the RF signal to the cable, wherein an output RF signal is transmitted in response to receiving the RF signal when the cable has the cable fault damage, and a receiver adapted to receive the output RF signal and establish a location of the cable fault damage.

### RELATED APPLICATION

This patent application claims priority benefit of U.S. Provisional Patent Application No. 63/780,758, filed on Mar. 31, 2025, the entire contents of which is herein incorporated by reference.

### BACKGROUND OF THE INVENTION

Locating faults in distribution network cable systems and radial underground cables is not exact. It can take several hours to days to find a fault using known techniques. Even with modern faulted circuit indicators and fault locating devices, it can be difficult to know with certainty a fault location is in a specific cable run without investigating into at least one manhole or underground access point.

Some available devices may use high potential direct current (DC) or alternating current (AC) signals to create an audible sound that crews must detect, the detection depending entirely on the environment of the fault. As many cables in duct banks will not make enough noise, it is impossible to detect the audible sound in busy areas with high public activity, such as downtown networks. Other available devices may use high potential AC or DC signals to “thump” a cable creating low impedance flash over to enable calculation of the electrical distance to the fault or directly measure fluctuating magnetic fields. However, such thumpers have difficulty in urban environments where there is substantial reinforced concrete between the surface and the cable, and the signal can be likewise or in addition to heavily attenuated and interfered with by nearby noise and electromagnetic (EM) sources, for example. Both of these methods are also destructive test methods that can further degrade the integrity of the cable system.

Some devices take advantage of reflected traveling EM waves in the cable to more accurately calculate the electrical distance to the fault to reasonably calculate a physical cable length to the fault. However, these methods do not account for branch points in the cable that are usually upline of the fault, adding more places for crews to check for the fault. Also, given the electrical properties of the cable are used to calculate a distance, several factors that are impossible to account for give a high range of possible distance to the fault. The practical effect is that it can sometimes take days (and entrance into numerous manholes) to identify the location of a fault. It would be desirable to provide a device for rapidly and accurately detecting electrical faults in underground cables.

### SUMMARY OF THE INVENTION

In accordance with a first aspect, a device for locating cable fault damage in a cable located underground comprises an RF signal generator which creates an RF signal, a transmitter transmitting the RF signal to the cable, wherein an output RF signal is transmitted in response to receiving the RF signal when the cable has the cable fault damage, and a receiver adapted to receive the output RF signal and identify the location of the cable fault damage.

### BRIEF DESCRIPTION OF THE DRAWINGS

FIG. 1 is a schematic view of a device for locating electrical faults in accordance with one embodiment.

FIG. 2 is a flow chart outlining a method of locating electrical faults using the device of FIG. 1

### DETAILED DESCRIPTION OF CERTAIN EMBODIMENTS

In the following detailed description of the invention, numerous details, examples, and embodiments of the invention are described. However, it will be clear to those skilled in the art that the invention disclosed herein is not limited to the embodiments set forth and that the invention can be adapted for any of several applications. This list of possible constituent elements is intended to be exemplary only, and it is not intended that this list be used to limit the present application to just these elements. Persons having ordinary skill in the art given the present disclosure may understand there to be equivalent elements that may be substituted within the present disclosure without changing the essential function or operation of the device. The various elements of the device of the present disclosure may be related in the following exemplary fashion. It is not intended to limit the scope or nature of the relationships between the various elements and the following examples are presented as illustrative examples only.

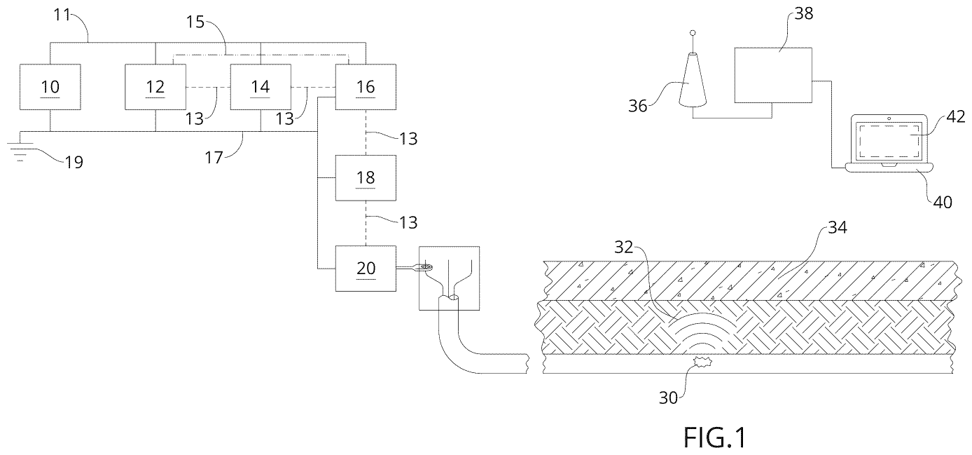

Turning now to the drawings, FIG. 1 shows a schematic of a device for locating electrical faults in cables, such as cables located underground and often below significant amounts of concrete, in accordance with one embodiment. An RF generator 12 is used to generate an RF signal, and the RF signal is transmitted by a transmitter to a cable to be inspected. When cable fault damage 30 is present in the cable, an RF output signal is transmitted from the cable damage point, which is typically much larger than a normal RF output signal generated when the cable does not have a fault. The output RF signal may be received by an RF receiver and related system 36, 38, 40, 42. This can be done by driving a motor vehicle containing the receiver and related system 36, 38, 40, 42 along a length of the cable (which can be several miles). The location where the RF output signal spikes is the location of the cable fault damage 30. This device and procedure for cable fault detection is highly advantageous in that fault inspection for many miles of buried cables can be carried out quickly, without having to repeatedly access the underground cables via manholes.

The RF signal generator 12 is operatively connected to the RF amplifier 14 via the RF output path 13, an RF amplifier 14 adapted to boost the RF signal from the RF signal generator, and antenna tuner 16. The DC power supply 10 is operatively connected to the RF signal generator 12, RF amplifier 14 and antenna tuner 16 via DC power path 11, and the RF signal generator 12 and antenna tuner 16 are operatively connected via tuning control path 15. The earth ground 19 provides electrical grounding to all electrical devices in the RF transmission section 10, 12, 14, 16, 18, 20 via direct electrical connection. A wattmeter 18 may be operatively connected to the antenna tuner via RF output path 13. A coupler 20 operatively connected to the RF generator must be used for coupling the RF signal to a phase conductor of the cable (with the fault). In electrical systems that do not use solidly grounded neutrals, a solid ground between the faulted cable's neutral jacket and earth ground should be connected prior to operation of the RF transmission system. Typically, the coupler acts as a transmitter and is operatively connected via inductance, so the RF signal propagates down the cable. The effect is to develop a stronger signal into the fault of cable 30 and radiating to the directional antenna 36 with little preventable loss, thereby enhancing the relative strength of the signal indicating a location of the fault in the cable. Use of the RF signal generator as disclosed here greatly reduces time to identify a location of a fault in an underground cable compared to existing technology due to direct measurement of the fault point and ease of detection through concrete 34 obstructions in an urban environment.

The RF signal generator may be provided with a transmitter menu which permits a user to select an electrical circuit voltage, cable type and estimated total length for the purpose of generating the frequency or frequencies and amplitude of the RF signal. An RF receiver 38, which may be battery powered and rechargeable, is adapted to receive the RF output signal 32 generated at the cable fault damage 30. It is understood that the fault RF signal is the only point other than at other degradation points along the neutral shielding on the cable where the RF output signal is relatively high and therefore more easily detected by the receiver 38. A normal, healthy medium to high voltage power cable has a continuous neutral jacket that provides electromagnetic shielding along it in order to protect against voltage induction on nearby objects, and therefore will not normally produce a large RF output signal. An RF coupler can comprise any inductive slip-on coupler designed for RF signals or a suitable voltage class rated connector customized with adequate shielding added to its design to avoid signal attenuation, such as 200A, 600A, 900A plugs and T-bodies as well as other capacitive clamp-on devices customized to be connected to the RF output of the transmitter system. The device disclosed here will also work for lower power levels on cables that are outside of heavily insulated areas.

A receiver data display 42 and laptop 40 can be used to view data about the output signal 32. The laptop is understood to be a laptop or other similar device that can integrate the output signal with other useful location information is operatively connected to the receiver and can measure the output signal strength at a signal measurement point or location, as well as create one or more GPS tags to indicate the signal strength and/or the location of the fault. Cable fault damage is understood herein to refer to a fault in the cable as well as to other points on the cable with weakened insulation or shielding integrity. The receiver is connected to an antenna 36 and may have a Bluetooth interface. The mobile RF receiver 38 can be tuned to the frequency of the transmitted output RF signal via either manual tuning or matching the cable type, estimated length and electrical system voltage selected via a transmitter menu. A mobile software application which may be downloadable for use with any suitable mobile device, such as a smartphone, may be provided to operate the device. The application may communicate wirelessly with the mobile RF receiver 38 via Bluetooth using the Bluetooth interface. The mobile software application 400 may operate detecting the mobile RF receiver 38 via Bluetooth, opening a map overlay and continuously displaying a measured output signal 32 strength. The mobile software application can thus provide a graphical display during the search for the fault location, adding convenience for the user.

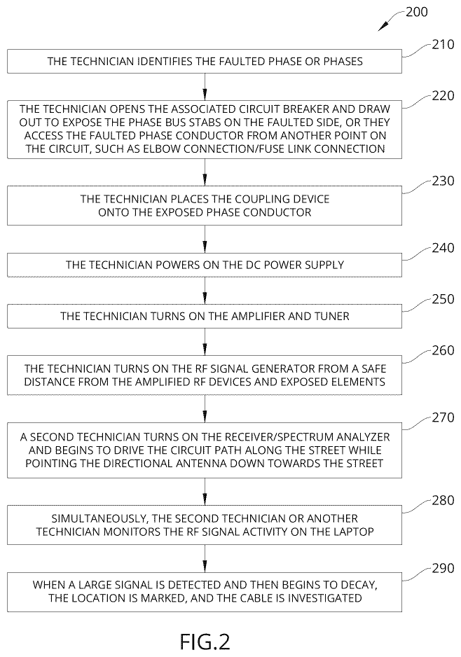

FIG. 2 outlines a proposed method 200 of detecting faults in underground electric cables in accordance with one embodiment. At a first step 210, a fault in an underground cable is identified and needs to be located. At step 220, an associated circuit breaker can be opened and drawn out to expose phase bus stabs on the faulted side. Alternatively, a phase conductor on the cable with the fault may be accessed from another point on the circuit, such as an elbow connection or link/fuse connection. At step 230, a coupling device is operatively connected to the exposed phase conductor. Next, the DC power supply is turned on, Step 240, then the tuner is turned on, and then at Step 250 the transceiver and amplifier turned on to a standby mode. At Step 260, the transceiver and amplifier are switched to an active power mode (from a safe distance from the amplified RF devices and the exposed elements), the power is ramped up either manually or to pre-programmed levels. At Step 270, a second technician (typically in a motor vehicle) turns on the receiver/spectrum analyzer and can drive along a circuit path (i.e., along the path of the underground cable) while pointing the directional antenna down towards the street. Typically, the radiated RF signal is strongest and received when the motor vehicle is generally adjacent the fault i.e., nearly directly above the fault. The data display can be monitored for the RF output signal, step 280. When a large output signal is detected and begins to decay, a location is identified, and the cable can be investigated, step 290.

Persons of ordinary skill in the art, given the benefit of this disclosure, may appreciate that numerous design configurations may be possible to enjoy the functional benefits of the inventive systems. Thus, given the wide variety of configurations and arrangements of embodiments of the present invention the scope of the invention is reflected by the breadth of the claims below rather than narrowed by the embodiments described above.

1. A device for locating cable fault damage in a cable located in the ground comprises, in combination:
an RF signal generator which creates an RF signal;
a transmitter transmitting the RF signal to the cable, wherein an output RF signal is transmitted in response to receiving the RF signal when the cable has the cable fault damage; and
a receiver adapted to receive the output RF signal and establish a location of the cable fault damage, wherein the receiver is located on a motor vehicle adapted to move along the cable, and the receiver is electrically isolated from the transmitter.

2. The device of claim 1 further comprising a clamp operatively connecting the RF signal generator to the underground cable.

3. The device of claim 1 further comprising a directional antenna pointed towards ground, adapted to directly receive the RF signal, and operatively connected to the receiver.

4. The device of claim 1 wherein the output RF signal is strongest when the receiver is adjacent the cable fault damage.

5. The device of claim 1 further comprising a power supply adapted to supply power to the RF signal generator.

6. The device of claim 1 further comprising an amplifier adapted to boost the RF signal from the RF signal generator.

7. The device of claim 1 wherein a laptop is operatively connected to the receiver and can create a GPS tag corresponding to the location of the cable fault damage.

8. The device of claim 7 wherein the GPS tag corresponds to a signal strength of the output signal.
